(19) United States
(12) Patent Application Publication
(10) Pub. No.: US 2011/0117332 A1
(43) Pub. Date: May 19, 2011

(54) ACRYLATE RESIN, PHOTORESIST COMPOSITION COMPRISING THE SAME, AND PHOTORESIST PATTERN

(75) Inventors: Hye Ran SEONG, Daejeon (KR); Kyoung Ho AHN, Daejeon (KR); Yu Na KIM, Daejeon (KR); Kyung Jun KIM, Daejeon (KR)

(73) Assignee: LG CHEM. LTD., Seoul (KR)

(21) Appl. No.: 12/939,870

(22) Filed: Nov. 4, 2010

Related U.S. Application Data
(63) Continuation of application No. PCT/KR2010/007678, filed on Nov. 2, 2010.

(30) Foreign Application Priority Data
Nov. 2, 2009 (KR) 10-2009-0105182

(51) Int. Cl. G03F 7/004; C08F 20/28; C08F 20/32; B32B 3/10

(52) U.S. Cl. 428/195.1; 430/270.1; 526/266; 526/273

(57) ABSTRACT

Disclosed are an acrylate resin included in a chemically amplified photoresist composition for forming a thick film, a chemically amplified photoresist composition including the same, and a photoresist pattern fabricated therefrom. The photoresist composition including the acrylate resin can achieve an improvement of sensitivity without damaging major characteristics such as compatibility (dispersion stability), spreading characteristics, developing characteristics, and resolution. In addition, a thick resist pattern can be formed with such a composition, and the pattern can have excellent sensitivity, developing characteristics, pattern characteristics, crack resistance, and plating resistance.

The present application claims priority to Korean Application No. 10-2009-0105182 filed in Korea on Nov. 2, 2009, the entire contents of which is hereby incorporated by reference in its entirety.

### BACKGROUND OF THE INVENTION

1. Field of the Invention

The present invention relates to an acrylate resin included in a chemically amplified photoresist composition for forming a thick film, a chemically amplified photoresist composition including the same, and a photoresist pattern fabricated therefrom.

2. Description of the Related Art

Recently, the reduction in size of electronic devise has triggered an additional advancement of high-density packing of a semiconductor package including a multi-pin thin film packing and the reduction in size of a semiconductor package, and an improvement in packing density based on a two-dimensional packing technique or a 3-dimensional packing technique using a flip-chip system, so the utilization of thick film photoresist for the foregoing type photomachining is gradually increasing.

The thick film photoresist is used to form a thick film photoresist layer. For example, the thick film photoresist is used to form a bump, a metal post, or the like, through a plating process.

The bump or the metal post may be formed by forming a thick photoresist layer having a film thickness of 20 μm on, for example, a support body, exposing and developing the thick photoresist layer through a certain mask pattern to form a resist pattern in which a portion for forming a bump or a metal post has been selectively removed (or exfoliated), filling the removed portion (i.e., a non-resist portion) with a conductor such as copper, or the like, through plating, and then removing the ambient resist pattern.

As the thick film photoresist, Japanese Patent Laid Open Publication No. 2002-258479 discloses a positive photosensitive resin composition having a compound containing a quinonediazide group used to form a pump or a wire (or line).

Meanwhile, a chemically amplified photoresist including an acid generating agent has been known as a photosensitive resin composition having a higher sensitivity than that of the conventional positive photosensitive resin composition having a compound containing a quinonediazide group.

The chemically amplified photoresist has characteristics that acid is generated from the acid generating agent through irradiation (exposure) and spreading of acid is accelerated according to heating after the exposure to cause acid catalysis over a base resin, or the like, of the resin composition to change alkali solubility. For example, as noted from Japanese Laid Open Publication No. 2001-281862 and Japanese Laid Open Publication No. 2001-281863, a chemically amplified photoresist composition for plating is disclosed as a positive type composition in which an alkali insoluble component of the chemically amplified photoresist is turned to be alkali soluble.

As mentioned above, a particular sector of the electronics industry requires a photoresist film thicker than that used for a lithography of high resolving power, and in this case, generally, the film thickness may not exceed 20 microns. In the thick film field, a physical parameter, firing, and developing of a coating film may be considerably different from those of a thin film. A thick coating film of photoresist may have defects such as a phase separation, striation, a formation of micro-bubble, and the like, because of these defects, a non-uniform film may be formed after coating or even after developing.

### SUMMARY OF THE INVENTION

Thus, an object of the present invention is to provide an acrylate resin included in a chemically amplified photoresist composition for a thick film appropriately used to form a connection terminal, a wiring pattern, and the like, of a bump, a metal post, and the like, in manufacturing electronic components such as a circuit board, a chip size package (CSP) mounted on the circuit board, a micro-electro-mechanical system (MEMS) element, a micro-machine having the MEMS element, a through electrode for performing a high density mounting, and the like, as an optimum photoresist composition to form a thick photoresist required in the sector of the recent electronic machine industry.

Another object of the present invention is to provide a chemically amplified photoresist composition for a thick film, including an acrylate resin, which can be easily exfoliated as well as having excellent sensitivity, developing characteristics, pattern characteristics, crack resistance, and plating resistance.

Still another object of the present invention is to provide a photoresist pattern of a thick film fabricated from the foregoing composition.

To achieve the above objects, there is provided an acrylate resin represented by Chemical Formula I shown below:

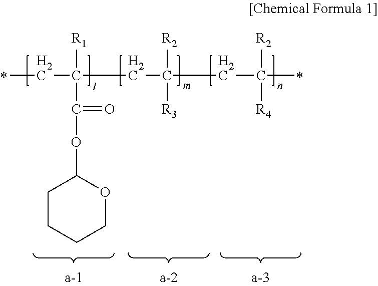

In Chemical Formula 1, R₁ and R₂ are the same or different, which are a methyl group or hydrogen, respectively, R₃ is one or more selected from the group consisting of substitution products including carboxylic acid, hydroxyl, and a lactone group, R₄ is one or more selected from the group consisting of a substituent, excluding R₃, and an aromatic group, and l, m, and n indicate mole ratios of a-1, a-2, and a-3, wherein l satisfies 40˜60 mol %, m satisfies 1˜10 mol %, and n satisfies 30˜59 mol %.

The acrylate resin may include an organic solvent of one or more selected from the group consisting of propylene glycolmonomethyletheracetate, N-methyl-2-pyrrolidone, N,N-dimethylformamide, N,N-dimethylacetamide, dimethylsulfoxide, diethylacetamide, γ-butyrolactoneketone, γ-valerolactoneketone, and m-cresol.

(a-1) of Chemical Formula I may include one or more selected from the group consisting of tetrahydro-2H-pyran-2-yl methacrylate and tetrahydro-2H-pyran-2-yl acrylate, and (a-2) of Chemical Formula I may include one or more selected from the group consisting of acrylic acid, crotonic acid, itaconic acid, maleic acid, fumaric acid, citraconic acid, mesaconic acid, acrylic acid glycidyl, methacrylic acid glycidyl, α-ethyl acrylic acid glycidyl, α-n-propyl acrylic acid glycidyl, α-n-butyl acrylic acid glycidyl, acrylic acid-3,4-epoxy butyl, methacrylic acid-3,4-epoxy butyl, acrylic acid 6,7-epoxy heptyl, methacrylic acid-6,7-epoxy heptyl, α-ethyl acrylic acid-6,7-epoxy heptyl, o-vinyl benzyl glycidyl ether, m-vinyl benzyl glycidyl ether, p-vinyl benzyl glycidyl ether, 2-hydroxyethylethyl (meth)acrylate, 2-hydroxyoctyl(meth)acrylate, 2-hydroxyethyl(meth) acrylate, and 2-hydroxy propyl(meth)acrylate.

(a-3) of Chemical Formula I may include one or more selected from olefin-based compounds selected from the group consisting of styrene, o-methyl styrene, m-methyl styrene, p-methyl styrene, vinyl toluene, p-methoxy styrene, acrylonitril, methacrylonitril, vinyl chloride, vinylidene chloride, acryl amide, methacryl amide, vinyl acetate, 1,3-butadiene, isoprene, 2,3-dimethyl-1,3-butadiene-phenylacrylate, phenylmethacrylate, 2 or 4-nitrophenylacrylate, 2 or 4-chlorophenylacrylate, and 2 or 4-chlorophenylmethacrylate.

Preferably, a weight-average molecular weight of the acrylate resin is 10,000 to 300,000.

To achieve the above objects, there is also provided a positive chemically amplified photoresist composition including the foregoing acrylate resin.

The acrylate resin may be included by 3 wt % to 60 wt % of a total amount of the chemically amplified photoresist composition.

The composition may include a) an acrylate resin of Chemical Formula 1; b) a photosensitive acid generating compound; c) an acid diffusion control agent; and d) a solvent.

The composition may include, a) over 100 weight parts of the acrylic resin of Chemical Formula 1, b) 0.01 weight parts to 30 weight parts of a photosensitive acid generating compound (PAG); c) 0.01 weight parts to 5 weight parts of the acid diffusion control agent; and d) 40 weight parts to 97 weight parts of a solvent.

The photosensitive acid generating compound may be one or more selected from the group consisting of triarylsulfonium salts, diaryliodonium salts, a sulfonate compound, triphenylsulfonium triflate, triphenylsulfonium antimonate, diphenyliodonium triflate, diphenyliodonium antimonate, methoxydiphenyliodonium triflate, di-t-butyliodonium triflate, 2,6-dinitobenzyl sulfonate, pyrogallol tris(alkylsulfonate), and succinimidyl triflate.

The acid diffusion control agent may be one or more selected from the group consisting of triethylamine, tripropyl amine, tribenzyl amine, trihydroxyethyl amine, and ethylene diamine.

To achieve the above objects, there is also provided a photoresist pattern fabricated from the positive chemically amplified photoresist composition.

The photoresist pattern may be a thick film having a film thickness ranging from 3 μm to 150 μm.

According to exemplary embodiments of the present invention, the photoresist composition including the acrylate resin can achieve an improvement of sensitivity without damaging major characteristics such as compatibility (dispersion stability), spreading characteristics, developing characteristics, and resolution.

In addition, a thick resist pattern can be formed with such a composition, and the pattern can have excellent sensitivity, developing characteristics, pattern characteristics, crack resistance, and plating resistance.

Thus, the photoresist composition including the acrylate resin can be applicable by using the thick resist pattern for extensive purposes in order to form a connection terminal, a wiring pattern, and the like, of a bump, a metal post, and the like, in manufacturing electronic components such as a circuit board, a chip size package (CSP) mounted on the circuit board, a micro-electro-mechanical system (MEMS) element, a micro-machine having the MEMS element, a through electrode for performing a high density mounting, and the like.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 3 are SEM photographs according to embodiments of the present invention and comparative examples.

### DETAILED DESCRIPTION OF THE INVENTION

Exemplary embodiments of the present invention will now be described in detail.

The terms used in the present application are merely used to describe particular embodiments, and are not intended to limit the present invention. An expression used in the singular encompasses the expression of the plural, unless it has a clearly different meaning in the context. In the present application, it is to be understood that the terms such as “including” and/or “comprising,” etc., are intended to indicate the existence of the features, numbers, operations, actions, components, parts, or combinations thereof disclosed in the specification, and are not intended to preclude the possibility that one or more other features, numbers, operations, actions, components, parts, or combinations thereof may exist or may be added.

The present invention provides an acrylate resin included in a chemically amplified photoresist composition for a thick film, a chemically amplified photoresist composition including the same, and a photoresist pattern fabricated therefrom.

1. Acrylate Resin

An acrylate resin according to an exemplary embodiment of the present invention is a compound represented by Chemical Formula I shown below:

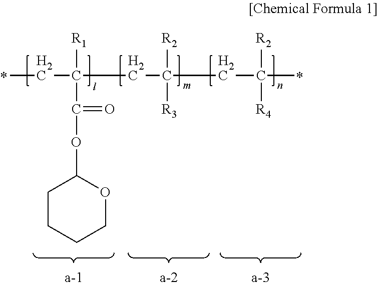

In Chemical Formula 1, R₁ and R₂ are the same or different, which are a methyl group or hydrogen, respectively, R₃ is one or more selected from the group consisting of substitution products including carboxylic acid, hydroxyl, and a lactone group, R₄ is one or more selected from the group consisting of a substituent, excluding R₃, and an aromatic group, and l, m, and n indicate mole ratios of a-1, a-2, and a-3, wherein l satisfies 40˜60 mol %, m satisfies 1˜10 mol %, and n satisfies 30˜59 mol %.

(a-1) of the acrylate resin includes a tetrahydropyranyl group at an end thereof. Having the substituent, (a-1) exhibits alkali insolubility, but when the tetrahydropyranyl group is separated from the resin due to acid generated from the photosensitive acid generating compound, the resin becomes acidic to have alkali solubility.

Namely, the tetrahydropyranyl group acts as a factor for adjusting the alkali solubility of the acrylate resin before and after exposure.

Preferably, (a-1) is included by 40 mol % to 40 mol % of the entire resin. Namely, 40 mol %≦1≦60 mol %. In this case, when 1 is less than 40 mol %, a developing speed with respect to a developer is too slow and when 1 exceeds 60 mol %, the remaining rate of the non-exposure area after developing is too low.

For example, a-1 may be selected from among tetrahydro-2H-pyran-2-yl methacrylate and tetrahydro-2H-pyran-2-yl acrylate.

(a-2) of the acrylate resin may be one or more selected from the group consisting of acrylate and methacrylate having carboxylic acid, hydroxyl, and a lactone group, and 1 mol % m 10 mol %.

For example, the monomer constituting (a-2) may be one or more selected from the group consisting of acrylic acid, crotonic acid, itaconic acid, maleic acid, fumaric acid, citraconic acid, mesaconic acid, acrylic acid glycidyl, methacrylic acid glycidyl, α-ethyl acrylic acid glycidyl, α-n-propyl acrylic acid glycidyl, α-n-butyl acrylic acid glycidyl, acrylic acid-3,4-epoxy butyl, methacrylic acid-3,4-epoxy butyl, acrylic acid-6,7-epoxy heptyl, methacrylic acid-6,7-epoxy heptyl, α-ethyl acrylic acid-6,7-epoxy heptyl, o-vinyl benzyl glycidyl ether, m-vinyl benzyl glycidyl ether, p-vinyl benzyl glycidyl ether, 2-hydroxyethylethyl(meth)acrylate, 2-hydroxyoctyl(meth)acrylate, 2-hydroxyethyl(meth)acrylate, and 2-hydroxy propyl(meth)acrylate.

The content of (a-3) is 35 mol % to 59 mol % of the entire resin. Namely, 30 mol % n 59 mol %. If n is less than 30 mol %, miscibility with PAG included in the following photoresist is low to make the solution cloudy, and if n exceeds 59 mol %, photo characteristics and a developing speed are insufficient.

The acrylate resin according to an exemplary embodiment of the present invention is fabricated by reacting one or more compounds selected from the group consisting of a-1) a compound including a tetrahydropyranyl group; a-2) a compound having carboxylic acid, hydroxyl, and a lactone group; and a-3) a compound including functional groups other than a-2) and a-3) and olefin-based compound.

An organic solvent used to synthesize an acryl binder resin may be one or more selected from the group consisting of propylene glycolmonomethyletheracetate, N-methyl-2-pyrrolidone, N,N-dimethylformamide, N,N-dimethylacetamide, dimethylsulfoxide, diethylacetamide, γ-butyrolactoneketone, γ-valerolactoneketone, and m-cresol.

In the above reaction, in order to form the photoresist layer having the film thickness required according to the present exemplary embodiment, each monomer includes 3 wt % to 60 wt % of solids over the entire resin.

Namely, if the content of the solids is less than 3 wt %, the resist composition including less than 3 wt % of the solids would have too low a viscosity, degrading an adhesive force with the substrate to make it difficult to form the thick photoresist layer. Conversely, when the content of the solids is more than 60 wt %, the resist composition would have too high a viscosity more than necessary, making it difficult to be coated with a uniform thickness, making it difficult to implement a smooth surface, and having a problem with a formation of a resist layer having a desired thickness. In addition, a uniform mixture can be hardly obtained in making a liquid, making it difficult to implement physical properties for forming a fine pattern.

The acrylate resin according to an exemplary embodiment of the present invention having the foregoing characteristics has a weight-average molecular weight ranging from 10,000 to 300,000.

If the weight-average molecular weight is too low as being less than 10,000, the film characteristics becomes inferior, and if the weight-average molecular weight is too high as being higher than 300,000, the solubility of the developer is degraded. In the present exemplary embodiment, the acrylic resin as described above serves as a backbone and the functional group such as (a-1) is introduced, thereby obtaining more advantageous effects in forming a thick photoresist layer compared with the related art.

2. Chemically Amplified Photoresist Composition for Thick Film

The present invention provides a photoresist composition for a thick film including the foregoing acrylate resin.

The photoresist composition forms an image by changing solubility of an alkali solution according to exposure. Thus, in order to obtain a desirous image, a change in the solubility of the alkali solution before exposure and during the exposure process is observed, from which a proper structure of a binder resin is derived. Thus, in the present exemplary embodiment, an acrylate resin including a tetrahydropyranyl group as a functional group assuming alkali solubility as it is broken by acid generated from a photosensitive acid generating compound (PAG) in the exposure process is included as a binder.

Preferably, the acrylate resin is included by 3 wt % to 60 wt % over the total amount of the photoresist composition of the present exemplary embodiment. If the acrylate resin is included by less than 3 wt %, the viscosity of the resist composition containing it would be too low to degrade adhesive force with the substrate to make it difficult to form a thick photoresist layer. Conversely, when the acrylate resin is included by more than 60 wt %, the viscosity of the composition is increased more than necessary to make it difficult to be coated with a uniform thickness, make it difficult to implement a smooth surface, and have a problem with a formation of a resist layer having a desired thickness. In addition, a uniform mixture can be hardly obtained in making a liquid, making it difficult to implement physical properties for forming a fine pattern.

“Thick film” mentioned throughout the specification of the present invention refers to a film formed to have a thickness ranging from 3 μm to 150 μm on the support body.

The photoresist composition according to an exemplary embodiment of the present invention may include: a) over 100 weight parts of the acrylic resin represented by Chemical Formula 1, b) 0.01 weight parts to 30 weight parts of a photosensitive acid generating compound (PAG); c) 0.01 weight parts to 5 weight parts of the acid diffusion control agent; and d) 40 weight parts to 97 weight parts of a solvent.

The photosensitive acid generating agent which can be used according to the present exemplary embodiment is a photosensitive acid generating compound generally used for a chemically amplified photosensitive composition, which may be one or more selected from the group consisting of triarylsulfonium salts, diaryliodonium salts, a sulfonate compound, triphenylsulfonium triflate, triphenylsulfonium antimonate, diphenyliodonium triflate, diphenyliodonium antimonate, methoxydiphenyliodonium triflate, di-t-butyliodonium triflate, 2,6-dinitobenzyl sulfonate, pyrogallol tris(alkylsulfonate) and succinimidyl triflate.

Preferably, the (b) photosensitive acid generating agent is used by 0.01 weight parts to 30 weight parts over 100 weight parts of the (a) acrylate binder resin. If the photosensitive acid generating agent is less than 0.01 weight parts, a developing speed would be too slow, and if the photosensitive acid generating agent exceeds 30 weight parts, an exposed area would become larger than a mask size during a developing operation and the straightness of a pattern profile would be degraded.

The (c) acid diffusion control agent is used to control diffusion of acid within the photoresist film. Thus, the dependency of the environment can be lowered, and thus, a change in the sensitivity can be controlled after exposure. A basic compound is largely used as the acid diffusion control agent, and examples thereof are as follows.

Namely, the acid diffusion control agent may be one or two or more selected from the group consisting of triethylamine, tripropyl amine, tribenzyl amine, trihydroxyethyl amine, and ethylene diamine.

Preferably, the (c) acid diffusion control gent is included by 0.01 weight parts to 5 weight parts over 100 weight parts of the (a) acrylate binder resin. If the acid diffusion control agent is less than 0.01 weight parts, a post exposure baking margin is reduced, and if the acid diffusion control agent exceeds 5 weight parts, photo characteristics are degraded.

The photosensitive resin composition according to the present exemplary embodiment is prepared by adding the photosensitive acid generating agent (PAG) and the acid diffusion control agent to the acryl binder resin produced as described above, and further adding a dissolution speed control agent, a sensitizing agent, an adhesion promoter, or surfactant, as necessary. Each of the additives may be added within the range of 0.1 weight parts to 30 weight parts over 100 weight parts of the acryl binder resin.

The solvent used for the photosensitive resin composition according to an exemplary embodiment of the present invention is not particularly limited; namely, any solvent may be used so long as it can dissolve the acryl binder.

For example, one or more selected from the group consisting of N-methyl-2-pyrrolidone, N,N-dimethylformamide, N,N-dimethylacetamide, dimethylsulf oxide, diethylacetamide, γ-butyrolactoneketone, γ-valerolactoneketone, m-cresol, ethyleneglycol monomethylether, ethyleneglycol monomethylether acetate, ethyleneglycol monoethylether, ethyleneglycol monoethylether acetate, ethyleneglycol monobutylether, ethyleneglycol monobutylether acetate, propyleneglycol monobutylether, ethyleneglycol monobutylether acetate, propyleneglycol monomethylether, propyleneglycol monomethylether acetate, propyleneglycol monoethylether, propyleneglycol monoethylether acetate, propyleneglycol monopropylether, propyleneglycol monopropylether acetate, propyleneglycol monobutylether, propyleneglycol monobutylether acetate, propyleneglycol dimethylether, propyleneglycol diethylether, propyleneglycol dipropyltilether, propyleneglycol dibutylether, ethyl lactate, butyl lactate, cyclohexanone, and cyclopentanone may be used.

Preferably, the photosensitive resin composition according to an exemplary embodiment of the present invention may include a solvent of 40 weight parts to 97 weight parts over 100 weight parts of the composition. If the solve is included to be less than 40 weight parts, it has a high viscosity more than necessary, failing to obtain a smooth surface when coated and having a problem with an implementation of a desired thickness, and a uniform mixture can be hardly obtained in making a liquid, which makes it difficult to implement physical properties for forming a fine pattern. If the solvent is included to exceed 97 weight parts, an adhesive strength with the substrate is degraded and a uniform coating characteristics and a desired film thickness can be hardly obtained.

A photoresist layer according to an exemplary embodiment of the present invention is preferably a positive photoresist layer.

3. Formation of Thick Photoresist Pattern

A resist pattern can be formed by using a thick photoresist laminated body by using the photoresist composition according to an exemplary embodiment of the present invention.

The thick photoresist laminated body is formed as thick photoresist layers composed of the photoresist composition according to an exemplary embodiment of the present invention are stacked on a support body.

The support body is not particularly limited and a conventional support body may be used. For example, a substrate for electronic components or a substrate having certain wiring patterns, and the like, may be used. The substrate may be, for example, a metal substrate made of silicon, silicon nitride, titanium, tantalum, palladium, titanium tungsten, copper, chromium, iron, aluminum, gold nickel, or the like, a glass substrate, or the like. The material of the wiring patterns may be, for example, copper, solder, chromium, aluminum, nickel, gold, or the like.

The thick photoresist laminated body may be fabricated as follows.

A solution of a photoresist composition is applied onto a support body and heated to remove a solvent to thereby form a desired coating film. In this case, in order to apply the solution of the photoresist composition onto the support body, a spin coating method, a slit coating method, a roll coating method, a screen printing method, an applicator method, or the like, may be employed. The coating film prebaking conditions of the composition according to the present exemplary embodiment may vary according to the kinds, mixture ratios, coating film thicknesses, and the like, of the respective components of the composition, and in general, the coating film prebaking conditions are 2 to 60 minutes generally at 70° C. to 150° C., and preferably, at 80° C. to 140° C.

The film thickness of the thick photoresist layer may range from 3 μm to 150 μm, preferably, 20 μm to 120 μm, and more preferably, 20 μm to 80 μm.

In order to form a resist pattern by using the thick photoresist laminated body, white light including I, H, and G is irradiated to the obtained thick photoresist layer by using a mask with certain patterns (or the thick photoresist layer is exposed). Then, the alkali solubility of the exposed portion of the thick photoresist layer is changed.

Active ray of light is a ray for activating the acid generating agent to generate acid, which may be ultraviolet ray, visible ray, or the like, and a low pressure mercury lamp, a high pressure mercury lamp, a super-high pressure mercury lamp, or the like, may be used. The amount of irradiated radiation may vary depending on the kinds, mixture ratios, coating film thicknesses, and the like, of the respective components of the composition. For example, in the case of using the super-high pressure mercury lamp, the amount of irradiated radiation is preferably 100 mJ/cm² to 10,000 mJ/cm².

After the exposure, a developing process is performed. In this case, before the developing process is performed following the exposure, a heating process is performed to accelerate spreading of acid. In the present exemplary embodiment, the PEB may be heated at 70° C. to 120° C. for one to ten minutes to promote spreading of acid.

In the developing process, for example, a certain alkali aqueous solution is used as a developer to dissolve and remove an unnecessary portion to thus obtain a certain resist pattern. As the developer, an alkali aqueous solution such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, dimethylethanolamine, triethanolamine, tetramethylammoniumhydroxyde, tetraethylammoniumhydroxide, pyrrole, piperidine, 1,8-diazabicyclo[5,4,0]-7-undecene, 1,5-diazabicyclo[4,3,0]-5-nonane, and the like, may be used. Also, an aqueous solution obtained by adding a suitable amount of an aqueous organic solvent such as methanol, ethanol, or the like, or a surfactant to the alkali aqueous solution may be used as a developer.

A developing time may vary depending on the kinds, mixture ratios of the respective components of the composition and a dried film thickness of the composition. In general, the developing time is one to 30 minutes, and a developing method may be any one of a spin method, a dipping method, a paddle method, a spray developing method, and the like. After the developing process, oil water cleansing is performed for 30 to 90 seconds and drying process is performed by using an air-conditioner, an oven, or the like.

A conductor such as metal, or the like, is buried in a non-resist portion (namely, a portion which has been removed by the alkali developer) of the thusly obtained resist pattern through, for example, plating, or the like, to thus form a connection terminal such as a metal post, a pump, or the like.

In this case, the plating method is not particularly limited and various conventionally known methods may be employed. As a plating solution, a solder plating solution, a copper plating solution, a gold plating solution, a nickel plating solution may be preferably used. The remaining resist pattern is finally removed by using a stripping solution, or the like, according to a determined rule.

The present invention will now be described more fully hereinafter. This invention may, however, be embodied in many different forms and should not be construed as being limited to the embodiments set forth herein. Rather, these embodiments are provided so that this disclosure will be thorough and complete, and will fully convey the scope of the invention to those skilled in the art.

### Synthesis Example 1

1 weight part of AlBN was used for 50 mol % of tetrahydropyranyl methacrylate, 10 mol % of methacrylic acid, and 40 mol % of styrene, and propyleneglycolmonomethyletheracetate was added to reach a total density of solids at 50 wt %. The resultant material was then polymerized at 60° C. for 15 hours to obtain a resin A-1 having a molecular weight of 150,000.

### Synthesis Example 2

1 weight part of AlBN was used for 40 mol % of tetrahydropyranyl methacrylate, 10 mol % of hydroxyethylmethacrylate, and 50 mol % of styrene, and propyleneglycolmonomethyletheracetate was added to reach a total density of solids at 50 wt %. The resultant material was then polymerized at 60° C. for 15 hours to obtain a resin A-2 having a molecular weight of 170,000.

### Synthesis Example 3

1 weight part of AlBN was used for 56 mol % of tetrahydropyranyl methacrylate, 3 mol % of methacrylic acid glycidyl, and 41 mol % of styrene, and propyleneglycolmonomethyletheracetate was added to reach a total density of solids at 50 wt %. The resultant material was then polymerized at 60° C. for 15 hours to obtain a resin A-3 having a molecular weight of 250,000.

### Embodiment

Components were mixed by the content indicated in Table 1 in propyleneglycolmonomethyletheracetate, evenly blended, and filtered with a syringe filter of 1 micron to produce each composition to have a total density of solids at 40 wt %.

TABLE 1

| | | Embodiment | Embodiment | Embodiment |
|---|---|---|---|---|
| Content: Weight parts | | 1 | 2 | 3 |
| Acrylate binder | A-1 | 100 | — | — |
| | A-2 | — | 100 | — |
| | A-3 | — | — | 100 |
| PAG | B-1 | 2 | — | — |
| | B-2 | — | 2 | 2 |
| Acid diffusion | C | 0.1 | 0.1 | 0.1 |
| inhibiter | | | | |

Note)
A-1, A-2, and A-3 were produced according to Synthesis Examples 1 to 3 B-1) triarylsulfonium salts. B-2) diaryliodonium salts. C) triethylamine

### Experimental Example

The prepared compositions of Embodiments 1 to 3 were spin-coated and dried at 120° C. for 3 minutes to obtain a photoresist layer having a thickness of 50 μm.

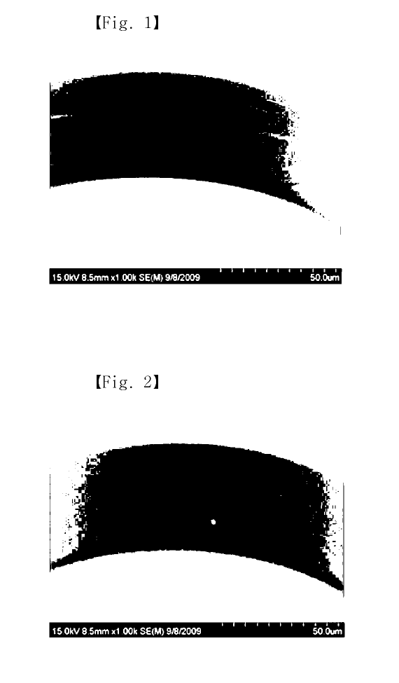

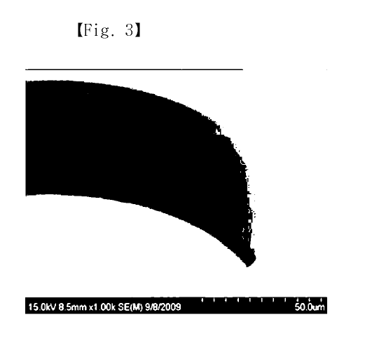

The thick photoresist layer was exposed with white light by using a mask of 100 μm hole patterns and then heated at 100° C. for two minutes. The resultant material was then developed in 2.38% tetramethylammoniumhydroxy aqueous solution and cleansed with distilled water and nitrogen-blown to obtain a pattern. The obtained pattern was observed by a scanning electron microscope, and the results are shown in FIGS. 1 to 3.

As shown in the SEM photographs of FIGS. 1 to 3, the pattern has excellent characteristics according to the observation of the profile of the pattern and checking residues. Thus, it can be noted that a thick resist pattern can be formed from the composition including the acrylate resin according to an exemplary embodiment of the present invention, and the formed resist pattern has excellent physical properties such as sensitivity, developing characteristics, and the like.

As the present invention may be embodied in several forms without departing from the characteristics thereof, it should also be understood that the above-described embodiments are not limited by any of the details of the foregoing description, unless otherwise specified, but rather should be construed broadly within its scope as defined in the appended claims, and therefore all changes and modifications that fall within the metes and bounds of the claims, or equivalents of such metes and bounds are therefore intended to be embraced by the appended claims.

1. An acrylate resin represented by Chemical Formula I shown below: 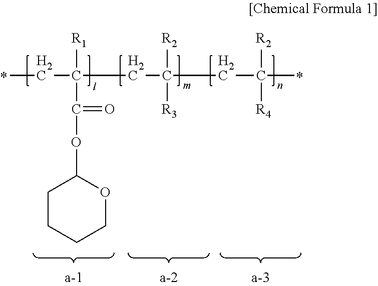
wherein R₁ and R₂ are the same or different, which are a methyl group or hydrogen, respectively, R₃ is one or more selected from the group consisting of substitution products including carboxylic acid, hydroxyl, and a lactone group, R₄ is one or more selected from the group consisting of a substituent, excluding R₃, and l is 40˜60 mol %, m is 1˜10 mol %, and n is 30˜59 mol %.

2. (canceled)

3. The acrylate resin of claim 1, wherein (a-1) of Chemical Formula I is one or more selected from the group consisting of tetrahydro-2H-pyran-2-yl methacrylate and tetrahydro-2H-pyran-2-yl acrylate.

4. The acrylate resin of claim 1, wherein (a-2) of Chemical Formula I is one or more selected from the group consisting of acrylic acid, crotonic acid, itaconic acid, maleic acid, fumaric acid, citraconic acid, mesaconic acid, acrylic acid glycidyl, methacrylic acid glycidyl, α-ethyl acrylic acid glycidyl, α-n-propyl acrylic acid glycidyl, α-n-butyl acrylic acid glycidyl, acrylic acid-3,4-epoxy butyl, methacrylic acid-3,4-epoxy butyl, acrylic acid-6,7-epoxy heptyl, methacrylic acid-6,7-epoxy heptyl, α-ethyl acrylic acid-6,7-epoxy heptyl, o-vinyl benzyl glycidyl ether, m-vinyl benzyl glycidyl ether, p-vinyl benzyl glycidyl ether, 2-hydroxyethylethyl(meth)acrylate, 2-hydroxyoctyl(meth)acrylate, 2-hydroxyethyl(meth)acrylate, and 2-hydroxy propyl(meth)acrylate.

5. The acrylate resin of claim 1, wherein (a-3) of Chemical Formula I is one or more selected from olefin-based compounds selected from the group consisting of styrene, o-methyl styrene, m-methyl styrene, p-methyl styrene, vinyl toluene, p-methoxy styrene, acrylonitril, methacrylonitril, vinyl chloride, vinylidene chloride, acryl amide, methacryl amide, vinyl acetate, 1,3-butadiene, isoprene, 2,3-dimethyl-1,3-butadiene-phenylacrylate, phenylmethacrylate, 2 or 4-nitrophenylacrylate, 2 or 4-chlorophenylacrylate, and 2 or 4-chlorophenylmethacrylate.

6. The acrylate resin of claim 1, wherein a weight-average molecular weight of the acrylate resin is 10,000 to 300,000.

7. A chemically amplified photoresist composition comprising the acrylate resin according claim 1.

8. The composition of claim 7, wherein the acrylate resin is included by 3 wt % to 60 wt % of a total amount of the chemically amplified photoresist composition.

9. The composition of claim 7, further comprising:
a) photosensitive acid generating compound;
b) an acid diffusion control agent; and
c) a solvent.

10. The composition of claim 9, wherein the composition comprises,
a) over 100 weight parts of the acrylic resin of Chemical Formula 1,
b) 0.01 weight parts to 30 weight parts of a photosensitive acid generating compound (PAG);
c) 0.01 weight parts to 5 weight parts of the acid diffusion control agent; and
d) 40 weight parts to 97 weight parts of a solvent.

11. The composition of claim 9, wherein the photosensitive acid generating compound is one or more selected from the group consisting of triarylsulfonium salts, diaryliodonium salts, a sulfonate compound, triphenylsulfonium triflate, triphenylsulfonium antimonate, diphenyliodonium triflate, diphenyliodonium antimonate, methoxydiphenyliodonium triflate, di-t-butyliodonium triflate, 2,6-dinitobenzyl sulfonate, pyrogallol tris(alkylsulfonate), and succinimidyl triflate.

12. The composition of claim 9, wherein the acid diffusion control agent is one or more selected from the group consisting of triethylamine, tripropyl amine, tribenzyl amine, trihydroxyethyl amine, and ethylene diamine.

13. A photoresist pattern fabricated from the chemically amplified photoresist composition according to claim 7.

14. The photoresist pattern of claim 13, wherein the photoresist pattern is a positive photoresist pattern.

15. The photoresist pattern of claim 13, wherein the phororesist pattern is a thick film having a film thickness ranging from 3 μm to 150 μm.
